(19) United States
(12) Patent Application Publication
(10) Pub. No.: US 2011/0291663 A1
(43) Pub. Date: Dec. 1, 2011

(54) PRINTING APPARATUS AND LIQUID DETECTION SENSOR INSPECTION METHOD

(75) Inventor: Yuichi Nishihara, Matsumoto-shi (JP)

(73) Assignee: SEIKO EPSON CORPORATION, Shinjuku-ku (JP)

(21) Appl. No.: 13/118,301

(22) Filed: May 27, 2011

(30) Foreign Application Priority Data
May 31, 2010 (JP) 2010-124558

(51) Int. Cl. G01R 31/02

(52) U.S. Cl. 324/537

(57) ABSTRACT

The printing apparatus applies a first waveform to the liquid detection sensor, and measures a second waveform output from the liquid detection sensor in response to the application of the first waveform. Based on a measurement result of the second waveform, the printing apparatus inspects whether the liquid detection sensor can be driven. Further, prior to the application of the first waveform to the liquid detection sensor, the printing apparatus measures the first waveform itself, and performs an inspection based on a measurement result of the first waveform.

### BACKGROUND

1. Technical Field

The present invention relates to a technique of inspecting a liquid detection sensor included in a liquid container mounted in a printing apparatus.

2. Related Art

There is known a technique of making use of a piezoelectric element as a liquid detection sensor for detecting the presence or absence of a liquid in a liquid container mounted in a printing apparatus (e.g., see JP-A-2009-255418). In the technique, a predetermined voltage waveform is applied to a piezoelectric element to cause electrostriction, and, based on a residual waveform produced by residual vibrations that occur after the electrostriction, the presence or absence of the liquid can be detected.

However, the voltage for driving a piezoelectric element is relatively high. Therefore, if a short-circuit occurs between a circuit for driving the piezoelectric element and another electronic device, a voltage exceeding the withstand voltage might be applied to the electronic device. Such a problem has been common in printing apparatuses capable of driving a liquid detection sensor. JP-A-2009-274438 is another related art example.

### SUMMARY

An advantage of some aspects of the invention is that, in a printing apparatus, whether a liquid detection sensor can be normally driven is inspected with high accuracy.

An aspect of the invention may be applied to applications described below.

### Application 1

According to an aspect of the invention, there is provided a printing apparatus in which a liquid container including a liquid detection sensor is mounted. The printing apparatus includes a waveform application unit that applies a first waveform to the liquid detection sensor, a measuring unit that measures a second waveform output from the liquid detection sensor in response to application of the first waveform, and an inspection unit that, based on a measurement result of the second waveform, performs an inspection of whether the liquid detection sensor is capable of being driven. The waveform application unit applies the first waveform to the measuring unit prior to application of the first waveform to the liquid detection sensor, the measuring unit measures the applied first waveform, and the inspection unit further performs the inspection based on a measurement result of the first waveform.

With such a configuration, not only a second waveform output from the liquid detection sensor but also a first waveform for output of the second waveform from the liquid detection sensor are measured. Therefore, based on a measurement result of the second waveform, it can be inspected whether the first waveform has been normally applied to the liquid detection sensor. Furthermore, based on a measurement result of the first waveform, it can be inspected whether the first waveform itself has been normally generated. It can thus be inspected with high accuracy whether the liquid detection sensor can normally be driven.

### Application 2

It is preferable that the waveform application unit generate, as the first waveform, a waveform having at least two types of voltages.

With such a configuration, an inspection can be performed on the basis of at least two types of voltages. Therefore, even if a short circuit or the like causes a certain voltage to be wrongly applied to the measuring unit, an inspection can be accurately performed.

### Application 3

In this configuration, it is preferable that any of the at least two types of voltages be a voltage lower than an input withstand voltage of the measuring unit.

With such a configuration, the input withstand voltage of the measuring unit can be decreased, which makes it possible to cut down on costs of parts.

### Application 4

It is preferable that the liquid container have a storage element, and any of the at least two types of voltages may be a voltage lower than an input withstand voltage of the storage element.

With such a configuration, the input withstand voltage of the storage element can be decreased, which makes it possible to cut down on costs of parts.

### Application 5

It is preferable that the inspection unit determine that a broken wire or a poor contact has occurred in a case where the measured second waveform represents a constant voltage regardless of the application of the first waveform.

With such a configuration, it is possible to detect a broken wire or a poor contact between the printing apparatus and the liquid detection sensor.

### Application 6

It is preferable that the inspection unit determine that a short-circuit has occurred in a case where the measured second waveform represents the same voltage as the at least two types of voltages that the first waveform has.

With such a configuration, it is possible, for example, to detect occurrence of a short-circuit in a liquid detection sensor.

### Application 7

It is preferable that the liquid detection sensor include a high-impedance capacitive element, the waveform application unit apply the first waveform to a first electrode of the capacitive element, and the measuring unit measure the second waveform output from a second electrode of the capacitive element.

With such a configuration, it is possible, for example, to inspect a liquid detection sensor using a piezoelectric element as a capacitive element.

### Application 8

In this case, it is preferable that the waveform application unit apply the first waveform to the first electrode, and then apply the first waveform to the second electrode, and the measuring unit measure the second waveform output from the second electrode, and then measure a second waveform output from the first electrode.

With such a configuration, an inspection can be performed with the polarity of the capacitive element reversed. This makes it possible to inspect with higher accuracy whether the liquid detection sensor can be normally driven.

### Application 9

It is preferable that the first waveform applied to the liquid detection sensor and the first waveform applied to the measuring unit be waveforms that are identical in form.

With such a configuration, an inspection can be performed using one type of a waveform. This can simplify the circuit configuration for generating a waveform.

Other aspects of the invention may provide configurations as an inspection method and a computer program, in addition to the foregoing configuration as the printing apparatus. Such a computer program may be recorded in a computer readable recording medium. As the recording medium, for example, various media such as a flexible disk, a compact disk read-only memory (CD-ROM), a digital versatile disk-read only memory (DVD-ROM), a magneto-optical disk, and a memory card can be used.

### BRIEF DESCRIPTION OF THE DRAWINGS

The invention will be described with reference to the accompanying drawings, wherein like numbers reference like elements.

FIG. 1 is an explanatory diagram illustrating a schematic configuration of a printing apparatus as an embodiment of the invention.

FIG. 2 is an explanatory diagram illustrating the internal configurations of an ink cartridge and a control circuit.

FIG. 3 is a flowchart of main inspection processing.

FIG. 4 is a detailed flowchart of main body inspection processing.

FIG. 5 is an explanatory graph illustrating an example of an inspection waveform.

FIG. 6 is a detailed flowchart of first sensor inspection processing.

FIG. 7 is an explanatory graph illustrating an example of the inspection waveform and a response waveform responding thereto.

FIG. 8 is an explanatory graph illustrating an example of the inspection waveform and the response waveform responding thereto.

FIG. 9 is an explanatory graph illustrating an example of the inspection waveform and the response waveform responding thereto.

FIG. 10 is a detailed flowchart of second sensor inspection processing.

FIG. 11 is a flowchart of liquid detection processing.

FIG. 12 is an explanatory diagram illustrating an example of a liquid detection waveform and a response waveform responding thereto.

### DESCRIPTION OF EXEMPLARY EMBODIMENT

An exemplary embodiment of the invention will be described in the following order: A. Apparatus Configuration, B. Inspection Processing, C. Liquid Detection Processing, and D. Modifications.

### A. Apparatus Configuration

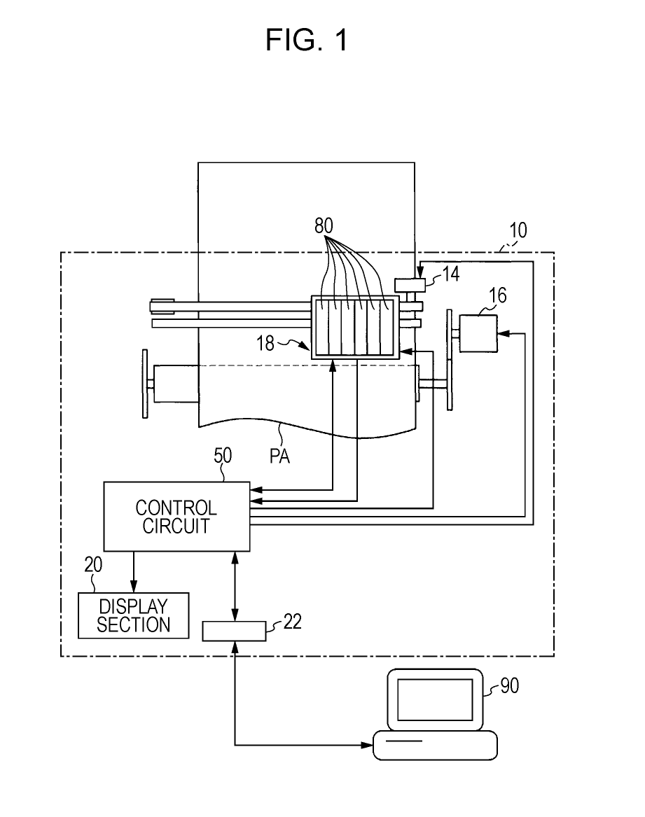

FIG. 1 is an explanatory diagram illustrating a schematic configuration of a printing apparatus as an embodiment of the invention. A printing apparatus 10 includes a carriage 12 on which ink cartridges 80 containing, for example, cyan, magenta, and yellow ink are mounted, a carriage motor 14 for driving the carriage 12 in a main-scanning direction, a paper feed motor 16 for transporting printing paper PA in a sub-scanning direction, a print head 18 that is mounted on the carriage 12 and discharges ink supplied from the ink cartridges 80, a display section 20 for displaying error information and the like, and a control circuit 50 for controlling the overall operation of the printing apparatus 10.

The control circuit 50 has a function for controlling the carriage motor 14, the paper feed motor 16, and the print head 18 on the basis of print data received from a computer 90 or the like connected via a predetermined interface 22, so that printing is performed. In this embodiment, the control circuit 50 further has a function of inspecting whether a liquid detection sensor included in the ink cartridge 80 can be normally driven. Hereinbelow, configurations and processing contents for implementing the inspection function will be described in detail.

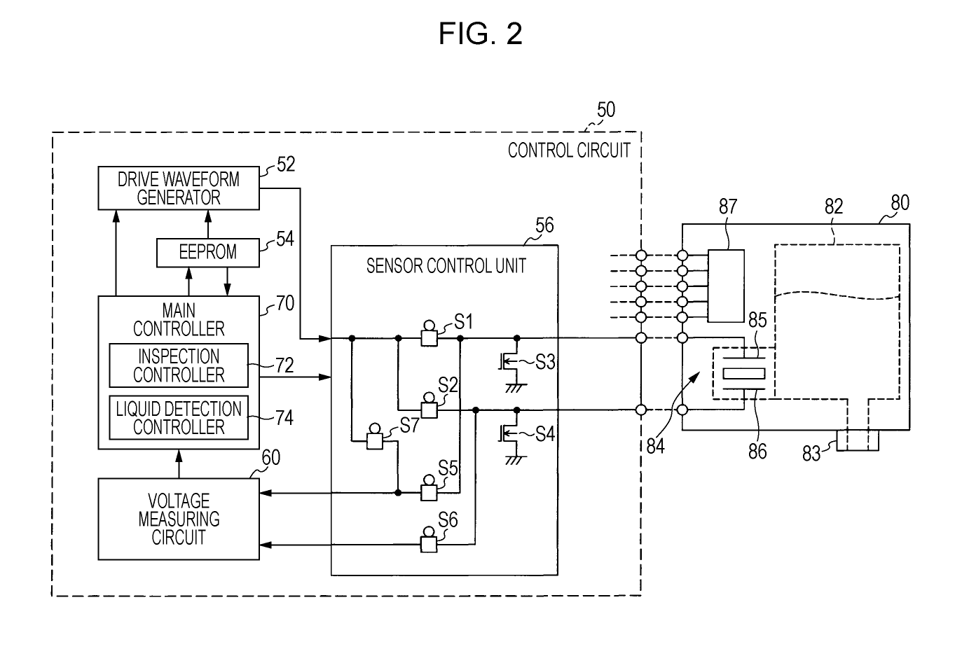

FIG. 2 is an explanatory diagram illustrating the internal configurations of the ink cartridge 80 and the control circuit 50. The ink cartridge 80 includes an ink containing chamber 82 containing ink therein, an ink supply port 83 for supplying ink contained in the ink containing chamber 82 to the print head 18, a liquid detection sensor 84 for detecting the presence or absence of ink in the ink containing chamber 82, and a non-volatile semiconductor memory 87 from and to which various information such as the amount of residual ink is read and written by the control circuit 50.

The liquid detection sensor 84 includes a piezoelectric element that is a high-impedance capacitive element, and is provided with a first electrode 85 and a second electrode 86 for driving the piezoelectric element. The first electrode 85, the second electrode 86, and electrodes included in the semiconductor memory 87 are electrically connected to the control circuit 50 through terminals on a circuit board (not illustrated) provided on the outer surface of the ink cartridge 80. It is to be noted that, for the semiconductor memory 87, the upper limit of a voltage that can be input to the semiconductor memory 87 (input withstand voltage) is defined, and is assumed to be 5 V in this embodiment.

The control circuit 50 includes a drive waveform generator 52, an electrically erasable programmable read-only memory (EEPROM) 54, a sensor control unit 56, a voltage measuring circuit 60, and a main controller 70.

The drive waveform generator 52 generates drive waveforms (voltage waveforms) for driving the liquid detection sensor 84 in response to a command from the main controller 70. Specifically, the drive waveform generator 52 reads drive waveforms stored as digital signals in the EEPROM 54, and converts the digital signals to analog signals, thereby generating drive waveforms as analog signals. It is to be noted that the drive waveform generator 52 can output drive waveforms for driving not only the liquid detection sensor 84 but also a piezoelectric element provided in the print head 18.

In the EEPROM 54, drive waveforms of a plurality of types in accordance with the purposes of operating the liquid detection sensor 84 are stored. Specifically, a drive waveform for detecting the presence or absence of a liquid in the ink cartridge 80 and a drive waveform for inspecting whether the liquid detection sensor 84 can be normally driven are stored. Hereinbelow, the former waveform is referred to as a “liquid detection waveform”, and the latter waveform is referred to as an “inspection waveform”. The inspection waveform corresponds to a “first waveform” of the present application.

The sensor control unit 56 includes, in the inside thereof, a plurality of switches S1 to S7, and changes the open and closed states of the switches S1 to S7 in accordance with commands from the main controller 70, thereby setting connection states of the drive waveform generator 52, the liquid detection sensor 84, and the voltage measuring circuit 60. As the switches S1, S2, S5, S6, and S7, for example, analog switches can be used. As the switches S3 and S4, for example, N-channel metal oxide semiconductor (NMOS) transistors can be used. In this embodiment, the sensor control unit 56 is provided on the carriage 12 and is connected to other circuits in the control circuit 50 by using a flexible flat cable (not illustrated).

When turned on, the switch S1 connects the drive waveform generator 52 with the first electrode 85 of the liquid detection sensor 84. When turned on, the switch S2 connects the drive waveform generator 52 with the second electrode 86 of the liquid detection sensor 84.

When turned on, the switch S3 grounds the first electrode 85 of the liquid detection sensor 84. Also, when turned on, the switch S4 grounds the second electrode of the liquid detection sensor 84.

When turned on, the switch S5 connects the first electrode 85 of the liquid detection sensor 84 with the voltage measuring circuit 60. Also, when turned on, the switch S6 connects the second electrode 86 of the liquid detection sensor 84 with the voltage measuring circuit 60.

When turned on, the switch S7 directly connects the drive waveform generator 52 with the voltage measuring circuit 60.

The voltage measuring circuit 60 has a function of measuring voltages of waveforms input through the sensor control unit 56 from the liquid detection sensor 84 and the drive waveform generator 52. The voltage measuring circuit 60 includes a voltage conversion circuit for converting the voltage range of an input waveform and an analog-to-digital (A/D) conversion circuit for converting an analog waveform to a digital signal. For the voltage measuring circuit 60, the upper limit of a voltage that can be input to the voltage measuring circuit 60 (input withstand voltage) is defined, and is assumed to be 5 V in this embodiment.

The main controller 70 is configured as a computer including a central processing unit (CPU), a random-access memory (RAM), and a read-only memory (ROM). The CPU loads control programs stored in the ROM into the RAM and executes the programs to function as an inspection controller 72 and a liquid detection controller 74.

The inspection controller 72 has a function of controlling the drive waveform generator 52, the sensor control unit 56, and the voltage measuring circuit 60 to inspect whether the liquid detection sensor 84 can be normally driven. Specific processing contents for implementing such a function will be described later.

The liquid detection controller 74 has a function of controlling the drive waveform generator 52, the sensor control unit 56, the voltage measuring circuit 60, and the liquid detection sensor 84 to detect the presence or absence of a liquid in the ink cartridge 80. Specific processing contents for implementing such a function will be described later.

### B. Inspection Processing

### B1. Main Inspection Processing

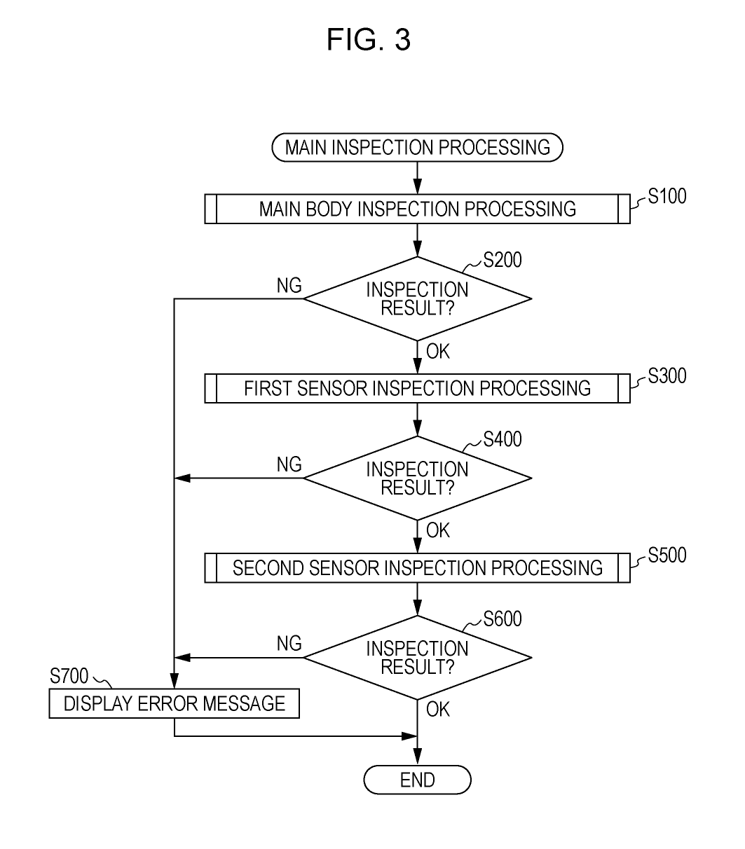

FIG. 3 is a flowchart of main inspection processing that is performed by the above-described inspection controller 72. The main inspection processing is performed when the printing apparatus 10 is powered on. Upon start of the main inspection processing, the inspection controller 72 first performs main body inspection processing (step S100). The main body inspection processing is processing for inspecting whether a drive waveform has been properly transmitted from the drive waveform generator 52 to the sensor control unit 56. The details of the processing will be described later.

When the main body inspection processing is completed, the inspection controller 72 determines whether the inspection result is “OK” or “NG” (step S200). If the inspection result is “OK”, that is, if it is confirmed that the drive waveform has been properly transmitted from the drive waveform generator 52 to the sensor control unit 56, then the inspection controller 72 performs first sensor inspection processing for each ink cartridge 80 mounted on the carriage 12 (step S300). The first sensor inspection processing is processing for inspecting whether a drive waveform has been properly transmitted from the drive waveform generator 52 to the first electrode 85 of the liquid detection sensor 84. The details of the processing will be described later. On the other hand, if the inspection result is “NG”, that is, if it is confirmed that the drive waveform has not been properly transmitted from the drive waveform generator 52 to the sensor control unit 56, the inspection controller 72 displays, on the display section 20, an error message saying something to the effect that the drive waveform has not been properly transmitted (step S700), and completes the main inspection processing.

When the first sensor inspection processing is completed, the inspection controller 72 determines whether the inspection result is “OK” or “NG” (step S400). If the inspection result is “OK”, that is, if it is confirmed that the drive waveform has been transmitted from the drive waveform generator 52 to the first electrode 85 of the liquid detection sensor 84, then the inspection controller 72 performs second sensor inspection processing for each ink cartridge 80 mounted on the carriage 12 (step S500). The second sensor inspection processing is processing for inspecting whether a drive waveform has been properly transmitted from the drive waveform generator 52 to the second electrode 86 of the liquid detection sensor 84. The details of the processing will be described later. On the other hand, in step S400, if the inspection result is “NG”, that is, if it is confirmed that the drive waveform has not been properly transmitted from the drive waveform generator 52 to the first electrode 85 of the liquid detection sensor 84, the inspection controller 72 displays, on the display section 20, an error message saying something to the effect that the drive waveform has not been properly transmitted (step S700), and the inspection controller 72 completes the main inspection processing. It is to be noted that in cases where the cause of an abnormality is identified by the first sensor inspection processing, indication of the cause of the abnormality is also provided in step S700.

When the second sensor inspection processing is completed, the inspection controller 72 determines whether the inspection result is “OK” or “NG” (step S600). If the inspection result is “OK”, that is, if it is confirmed that the drive waveform has been transmitted from the drive waveform generator 52 to the second electrode 86 of the liquid detection sensor 84, the inspection controller 72 normally completes the main inspection processing. On the other hand, in step S600, if the inspection result is “NG”, that is, if it is confirmed that the drive waveform has not been properly transmitted from the drive waveform generator 52 to the second electrode 86 of the liquid detection sensor 84, the inspection controller 72 displays, on the display section 20, an error message saying something to the effect that the drive waveform has not been properly transmitted (step S700), and the inspection controller 72 completes this sensor inspection processing. It is to be noted that in cases where the cause of an abnormality is identified by the sensor inspection processing, indication of the cause of the abnormality is also provided in step S700. In the main inspection processing described above, if the inspection results of all the inspections processing are “OK”, the control circuit 50 performs, by means of the liquid detection controller 74, liquid detection processing for detecting the presence or absence of ink in the ink cartridge 80 (the details will be described later).

### B2. Main Body Inspection Processing

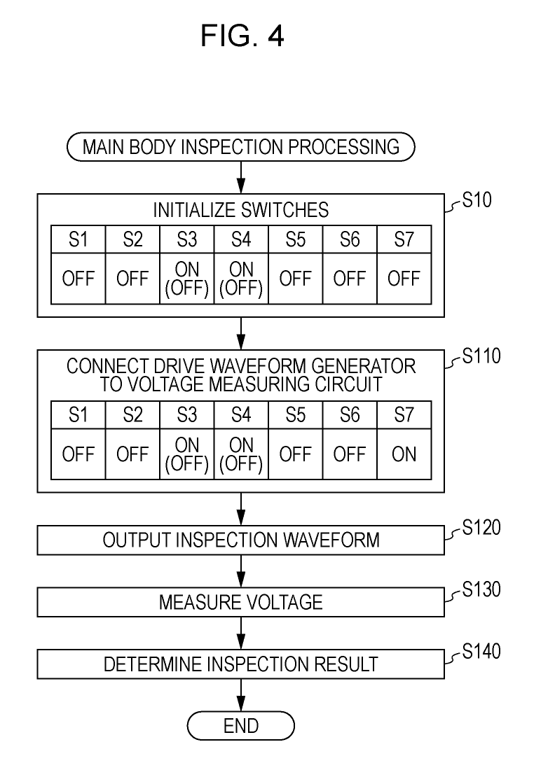

FIG. 4 is a detailed flowchart of the main body inspection processing that is performed in step S100 of the above-described main inspection processing. When the main body inspection processing is performed, the inspection controller 72 first initializes switches in the sensor control unit 56 (step S10). Specifically, the switch S3 and the switch S4 are turned on, and the other switches S1, S2, S5, S6, and S7 are turned off. Thus, both the first electrode 85 and the second electrode 86 of the liquid detection sensor 84 are in the grounded state.

The inspection controller 72 subsequently changes the switch S7 from the off-state to the on-state, thereby connecting the drive waveform generator 52 to the voltage measuring circuit 60 (step S110). Then, the inspection controller 72 provides a command to the drive waveform generator 52 to output an inspection waveform (step S120). As a result, the inspection waveform output from the drive waveform generator 52 is input via the sensor control unit 56 to the voltage measuring circuit 60.

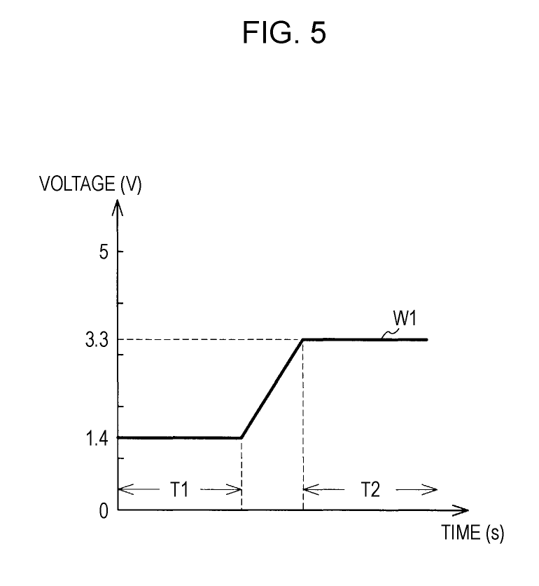

FIG. 5 is an explanatory graph illustrating an example of an inspection waveform W1. As illustrated, in this embodiment, a waveform in which a first voltage is applied during a first period T1, and a second voltage higher than the first voltage is applied subsequently during a second period T2 is output as the inspection waveform W1 from the drive waveform generator 52. The first voltage can be assumed to be, for example, 1.4 V, and the second voltage can be assumed to be, for example, 3.3 V. Both the first voltage and the second voltage are set lower than the input withstand voltage of the voltage measuring circuit 60.

Subsequently, the inspection controller 72 measures, using the voltage measuring circuit 60, the first voltage and the second voltage of the inspection waveform W1 input to the voltage measuring circuit 60 (step S130). Based on the measured result, it is determined whether a drive waveform is properly transmitted from the drive waveform generator 52 to the sensor control unit 56 (step S140). That is, if the first voltage and the second voltage measured in step S130 agree with the first voltage and the second voltage output from the drive waveform generator 52 in step S120, respectively, the inspection result is determined to be “OK”. On the other hand, if the first voltages do not agree with each other or the second voltages do not agree with each other, the inspection result is determined to be “NG”.

According to the main body inspection processing described above, the conduction state from the drive waveform generator 52 to the sensor control unit 56 or the conduction state from the sensor control unit 56 to the voltage measuring circuit 60 can be inspected. This makes it possible to determine whether an abnormality has occurred in a circuit on the side of the printing apparatus 10, not on the side of the ink cartridge 80. It is to be noted that, in this embodiment, the above-described main body inspection processing is performed with the switch S3 and the switch S4 of the sensor control unit 56 turned on and with both the first electrode 85 and the second electrode 86 of the liquid detection sensor 84 grounded. The main body inspection processing, however, may be performed with the switch S3 and the switch S4 turned off, and with the first electrode 85 and the second electrode 86 opened.

### B3. First Sensor Inspection Processing

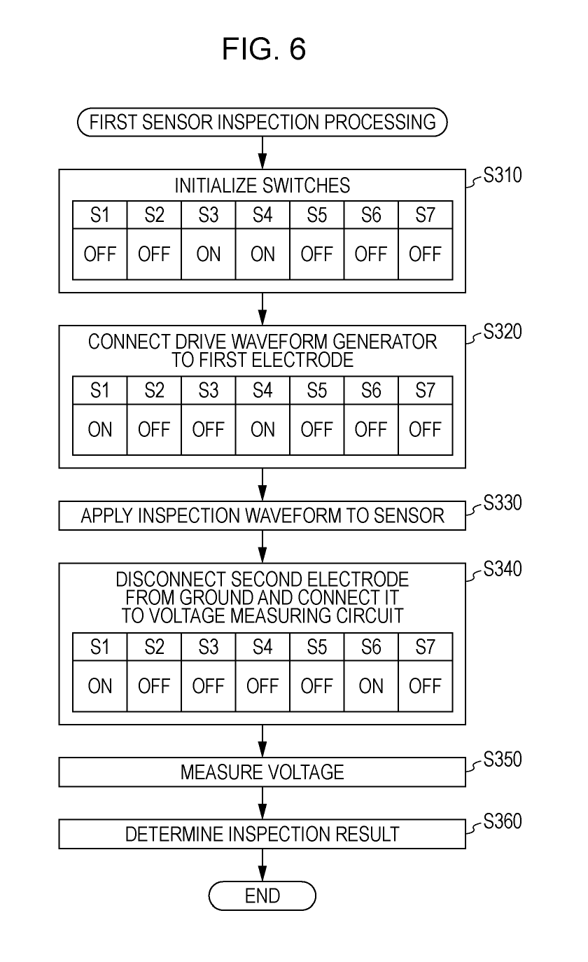

FIG. 6 is a detailed flowchart of the first sensor inspection processing that is performed in step S300 of the above-described main inspection processing. When the first sensor inspection processing is performed, the inspection controller 72 first initializes switches in the sensor control unit 56 (step S310). Specifically, the switch S3 and the switch S4 are turned on, and the other switches S1, S2, S5, S6, and S7 are turned off. Thus, both the first electrode 85 and the second electrode 86 of the liquid detection sensor 84 are in the grounded state.

Subsequently, the inspection controller 72 turns on the switch S1 and turns off the switch S3, thereby connecting the drive waveform generator 52 with the first electrode 85 of the liquid detection sensor 84 (step S320). Then, the inspection controller 72 provides a command to the drive waveform generator 52 to output the inspection waveform W1 illustrated in FIG. 5 (step S330). As a result, the inspection waveform W1 is applied to the first electrode 85 of the liquid detection sensor 84.

After a predetermined time period has elapsed since the start of application of the inspection waveform W1 to the first electrode 85, the inspection controller 72 turns off the switch S4 to disconnect the second electrode 86 of the liquid detection sensor 84 from the ground, and further turns on the switch S6 to connect the second electrode 86 of the liquid detection sensor 84 to the voltage measuring circuit 60 (step S340). Then, the inspection controller 72 measures, by means of the voltage measuring circuit 60, the first voltage and the second voltage of a response waveform output from the second electrode 86 of the liquid detection sensor 84 (step S350).

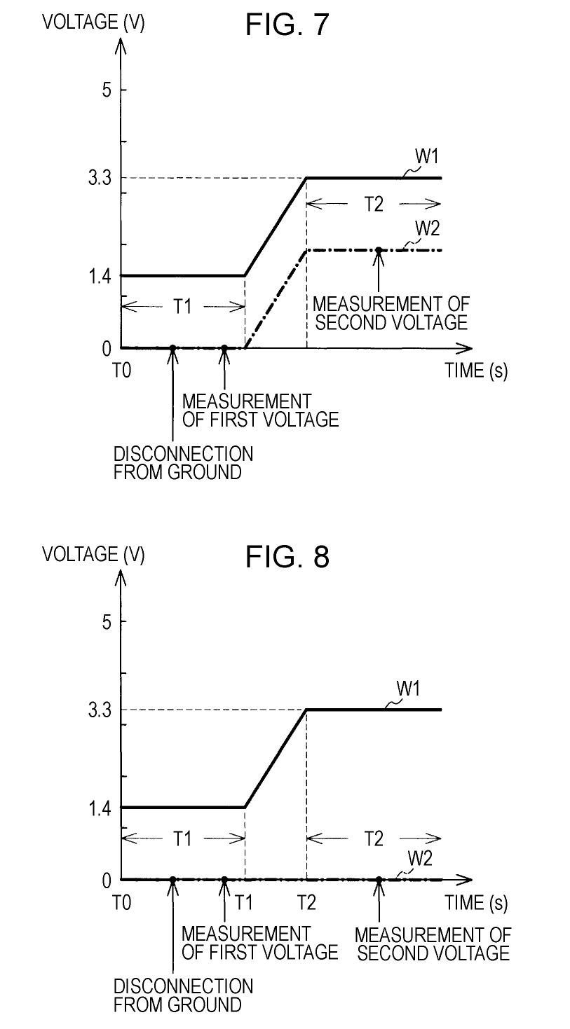

FIGS. 7 to 9 are explanatory graphs illustrating examples of the inspection waveform W1 and a response waveform W2. In these figures, the voltage waveform indicated by a solid line is the inspection waveform W1, and the voltage waveform indicated by a dot-and-dash line is the response waveform W2 output from the second electrode 86. The response waveform W2 corresponds to a “second waveform” of the present application. As illustrated in these figures, in this embodiment, after application of the inspection waveform W1 to the first electrode 85 starts, the second electrode 86 is disconnected from the ground during the first period T1 in the step S340. At a timing after the disconnection during the first period T1, the first voltage of the response waveform W2 is measured, and then in the second period T2 in which the applied voltage is raised, the second voltage of the response waveform W2 is measured.

When the first voltage and the second voltage of the response waveform W2 have been measured in step S350 mentioned above, based on these voltages, the inspection controller 72 determines whether there is an abnormality in a circuit between the sensor control unit 56 and the liquid detection sensor 84 (step S360). For example, when conduction from the sensor control unit 56 to the liquid detection sensor 84 is properly established, the response waveform W2 from the second electrode 86 has a shape that follows the inspection waveform W1 while keeping a predetermined potential difference from the inspection waveform W1 as illustrated in FIG. 7. At this point, for example, the first voltage of the response waveform W2 is 0 V, and the second voltage is about 2 V. Therefore, in cases where the values of the first voltage and the second voltage measured in step S250 agree with the values at this point, the inspection controller 72 determines in step S360 that there is no abnormality (OK). In other cases, the inspection controller 72 determines that there is an abnormality (NG).

In cases where it is determined in step S360 mentioned above that “there is an abnormality”, if a broken wire or a poor contact occurs between the sensor control unit 56 and the first electrode 85 of the liquid detection sensor 84, the inspection waveform W1 is not normally applied to the liquid detection sensor 84. Therefore, in this case, as illustrated in FIG. 8, after the second electrode 86 is disconnected from the ground, the response waveform W2 remains at 0 V. Accordingly, if the two voltages measured in step S350 mentioned above are both 0 V, the inspection controller 72 determines in step S360 mentioned above that the cause of the abnormality is “a broken wire or a poor contact between the sensor control unit 56 and the first electrode 85 of the liquid detection sensor 84”.

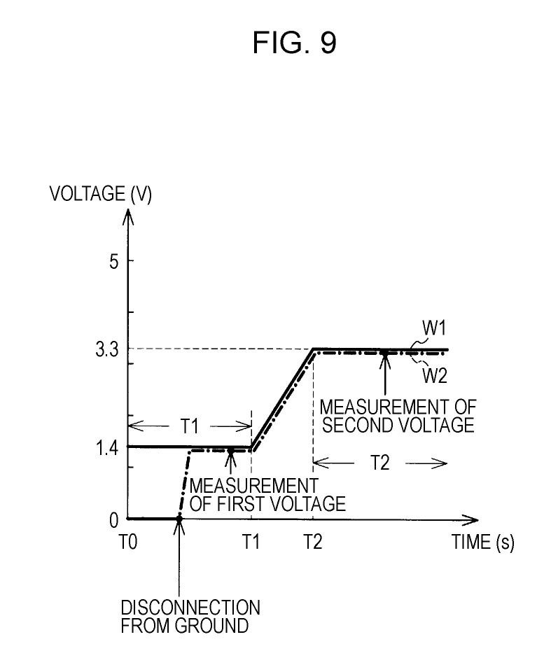

For example, if the first electrode 85 and the second electrode 86 of the liquid detection sensor 84 are short-circuited, then the inspection waveform W1 will be applied not only to the first electrode 85 but also to the second electrode 86. Therefore, in this case, as illustrated in FIG. 9, the response waveform W2 is the same waveform as the inspection waveform W1, after the second electrode 86 is disconnected from the ground. Accordingly, if both the first voltage and the second voltage measured in step S350 mentioned above have the same values as the first voltage and the second voltage of the inspection waveform W1, respectively, the inspection controller 72 determines in step S360 mentioned above that the cause of the abnormality is “a short-circuit between the first electrode 85 and the second electrode 86 of the liquid detection sensor 84”.

As described above, according to the first sensor inspection processing of this embodiment, the conduction state from the sensor control unit 56 to the first electrode 85 of the liquid detection sensor 84 can be inspected. Furthermore, in cases where an abnormality occurs, the cause of the abnormality can be identified on the basis of a difference between two types of voltages of the inspection waveform W1 and voltages of the response waveform W2.

### B4. Second Sensor Inspection Processing

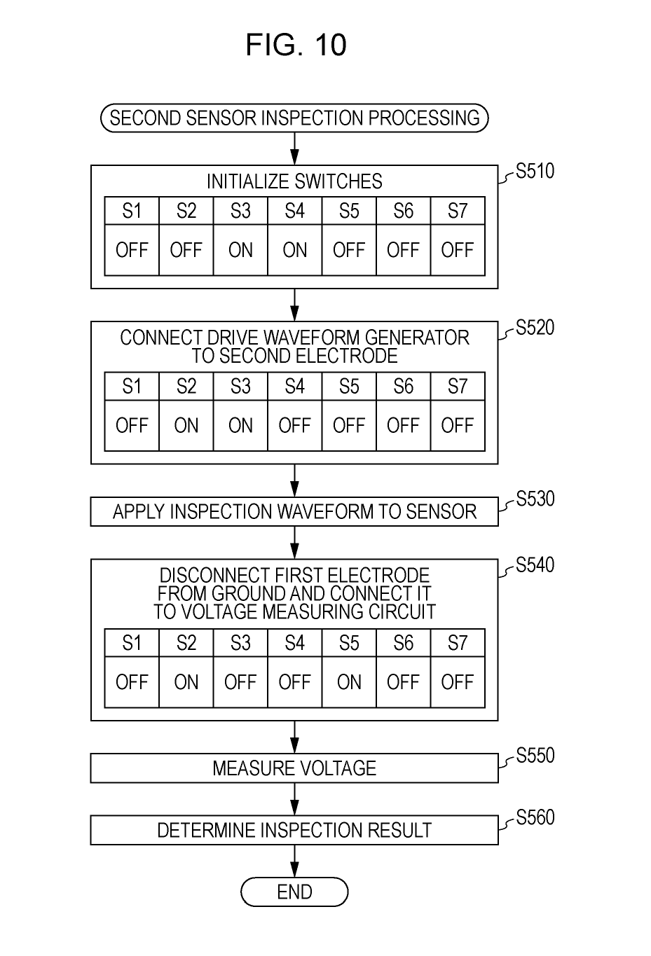

FIG. 10 is a detailed flowchart of the second sensor inspection processing that is performed in step S500 of the above-described main inspection processing. When the second sensor inspection processing is performed, the inspection controller 72 first initializes switches in the sensor control unit 56 (step S510). Specifically, the switch S3 and the switch S4 are turned on, and the other switches S1, S2, S5, S6, and S7 are turned off. Thus, both the first electrode 85 and the second electrode 86 of the liquid detection sensor 84 are in the grounded state.

Subsequently, the inspection controller 72 turns on the switch S2 and turns off the switch S4, thereby connecting the drive waveform generator 52 with the second electrode 86 of the liquid detection sensor 84 (step S520). Then, the inspection controller 72 provides a command to the drive waveform generator 52 to output the inspection waveform W1 illustrated in FIG. 5 (step S530). As a result, the inspection waveform W1 is applied to the second electrode 86 of the liquid detection sensor 84.

After a predetermined time period has elapsed since the start of application of the inspection waveform W1 to the second electrode 86, the inspection controller 72 turns off the switch S3 to disconnect the second electrode 86 of the liquid detection sensor 84 from the ground, and further turns on the switch S5 to connect the first electrode 85 of the liquid detection sensor 84 to the voltage measuring circuit 60 (step S540). Then, the inspection controller 72 measures, by means of the voltage measuring circuit 60, the first voltage and the second voltage of a response waveform output from the first electrode 85 of the liquid detection sensor 84 (step S550), and the presence or absence of an abnormality is determined as in the above-described first sensor inspection processing (step S560). At this point, for example, if the response waveform W2 as illustrated in FIG. 8 is obtained from the first electrode 85 of the liquid detection sensor 84, the inspection controller 72 determines that the cause of the abnormality is “a broken wire or a poor contact between the sensor control unit 56 and the second electrode 86 of the liquid detection sensor 84”. If the response waveform W2 as illustrated in FIG. 9 is obtained, the inspection controller 72 determines that the cause of the abnormality is “a short-circuit between the first electrode 85 and the second electrode 86 of the liquid detection sensor 84”.

As described above, according to the second sensor inspection processing of this embodiment, the conduction state from the sensor control unit 56 to the second electrode 86 of the liquid detection sensor 84 can be inspected. Furthermore, in cases where an abnormality occurs, the cause of the abnormality can be identified on the basis of a difference between two types of voltages of the inspection waveform W1 and voltages of the response waveform W2.

### C. Liquid Detection Processing

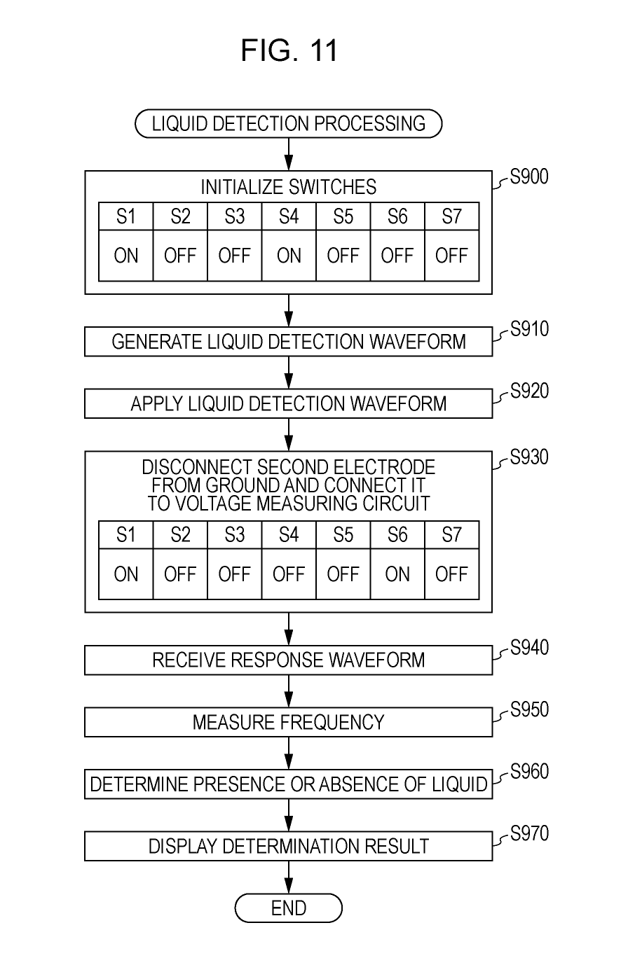

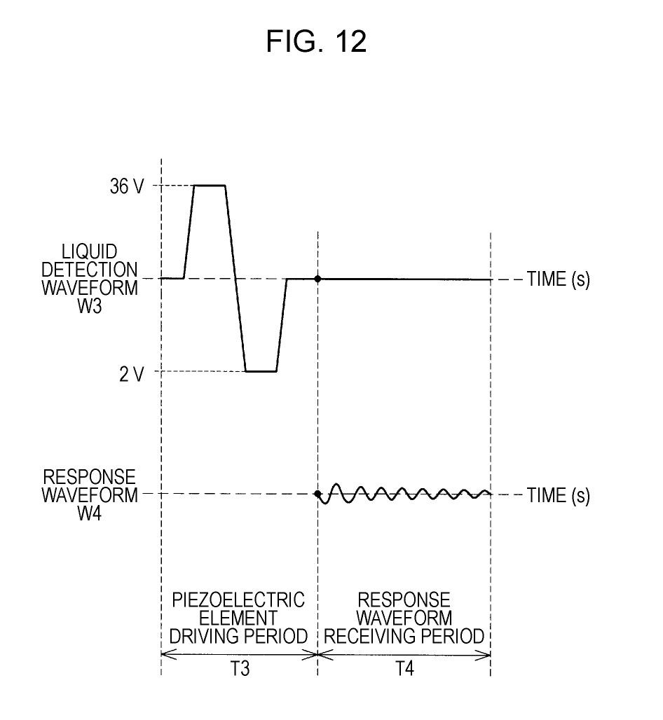

FIG. 11 is a flowchart of the liquid detection processing that is performed by the above-described liquid detection controller 74. FIG. 12 is an explanatory diagram illustrating an example of a liquid detection waveform for detecting ink in the ink cartridge 80 and a response waveform that responds to the liquid detection waveform. The liquid detection processing illustrated in FIG. 11 is performed if all the inspections are determined to be “OK” in the above-described main inspection processing.

When the liquid detection processing starts, the liquid detection controller 74 first provides a command to the sensor control unit 56 to initialize switches (step S900). Specifically, the switches S1 and S4 are turned on, and the switches S2, S3, S5, S6, and S7 are turned off. Thus, the drive waveform generator 52 is connected with the first electrode 85 of the liquid detection sensor 84, and thus the second electrode 86 of the liquid detection sensor 84 is in the grounded state.

The liquid detection controller 74 next provides a command to the drive waveform generator 52 to generate a liquid detection waveform W3 (see FIG. 12) (step S910). Upon receiving the command from the liquid detection controller 74, the drive waveform generator 52 reads data of the liquid detection waveform W3 from the EEPROM 54, and generates the liquid detection waveform W3 as illustrated in FIG. 12. Specifically, the drive waveform generator 52 generates the liquid detection waveform W3 that has a pulse shape of a combination of two mutually inverted trapezoids during a piezoelectric element driving period T3 for driving a piezoelectric element, and has such a shape as to keep a constant voltage during a response waveform receiving period T4 for receiving a response waveform W4 from the piezoelectric element. The liquid detection waveform W3 has a maximum voltage of about 36 V and has a minimum voltage of about 2 V.

When the liquid detection waveform W3 has been generated as described above, the liquid detection waveform W3 is applied to the first electrode 85 of the liquid detection sensor 84 by the drive waveform generator 52 (step S920). Thereafter, at the end of the piezoelectric element driving period T3, the liquid detection controller 74 provides a command to the sensor control unit 56. As a result, the switch S4 is turned off while the switch S1 remains in the on state, so that the second electrode 86 of the liquid detection sensor 84 is disconnected from the ground, whereas the switch S6 is turned on, so that the second electrode 86 is connected to the voltage measuring circuit 60 (step S930). Thus, as illustrated in FIG. 12, the response waveform W4 that oscillates in a predetermined period is output from the second electrode 86 of the liquid detection sensor 84.

The liquid detection controller 74 receives the response waveform W4 from the liquid detection sensor 84 through the sensor control unit 56 and the voltage measuring circuit 60 (step S940). Upon receiving the response waveform W4, the liquid detection controller 74 measures the frequency of the response waveform W4 (step S950), and determines, on the basis of the measured frequency, the presence or absence of ink in the ink cartridge 80 (step S960). The liquid detection sensor 84, the details of which are not illustrated, includes a cavity (resonance portion) that forms part of an ink flow channel extending from the ink containing chamber 82 to the ink supply port 83, a vibration plate that forms part of a wall surface of the cavity, and a piezoelectric element disposed on the vibration plate. When the liquid detection waveform W3 is supplied to the piezoelectric element, the vibration plate vibrates through the piezoelectric element. Thereafter, residual vibrations of the vibration plate occur, and the frequency of the residual vibrations is the frequency of the response waveform W4. The frequency of the residual vibrations of the vibration plate differs depending on the presence or absence of ink in the cavity. The liquid detection controller 74 can therefore detect the presence or absence of ink in the ink cartridge (to be precise, the presence or absence of ink in the cavity) by measuring the frequency of the response waveform W4. The liquid detection controller 74 causes the display section 20 and the computer 90 included in the printing apparatus 10 to display a result determined in this way (step S970).

It is to be noted that, in the above-described liquid detection processing, the liquid detection waveform W3 is applied to the first electrode 85 of the liquid detection sensor 84 to acquire the response waveform W4 from the second electrode 86. In contrast, for example, the liquid detection waveform W3 may be applied to the second electrode 86 of the liquid detection sensor 84 to acquire the response waveform W4 from the first electrode 85.

In the printing apparatus 10 of this embodiment described above, the foregoing main inspection processing is performed first, prior to the liquid detection processing for detecting the presence or absence of ink in the ink cartridge 80, so that it is inspected whether a drive waveform can be normally transferred from the drive waveform generator 52 to the liquid detection sensor 84. Therefore, it can be reduced or eliminated that, because of short-circuiting or the like, a high-voltage waveform (the liquid detection waveform W3) for driving the liquid detection sensor 84 is applied to the semiconductor memory 87 or the voltage measuring circuit 60 whose input withstand voltages are low.

In this embodiment, using a voltage waveform (the inspection waveform W1) lower than the input withstand voltages of the semiconductor memory 87 and the voltage measuring circuit 60, but not using a high-voltage waveform (the liquid detection waveform W3) for driving the liquid detection sensor 84, it is determined whether a drive waveform can be normally transferred from the drive waveform generator 52 to the liquid detection sensor 84. Therefore, the withstand voltages of the semiconductor memory 87 and the voltage measuring circuit 60 can be decreased, which makes it possible to cut down on costs of employed parts. Furthermore, in this embodiment, the inspection waveform W1 for the main body inspection processing and the inspection waveform W1 for the first and second sensor inspection processing are made identical in form. This can save the storage capacity of the EEPROM 54 in which data for generating the inspection waveform W1 is stored.

Also, in this embodiment, the inspection waveform W1 is made up of voltages of two types (the first voltage and the second voltage), and the presence or absence of an abnormality is determined on the basis of differences in voltage between these voltages and those of the response waveform (or the inspection waveform itself). Therefore, even if, because of short-circuiting or the like, a certain voltage is applied to a circuit to be inspected from another circuit, the certain voltage can be prevented from causing a false determination of the presence or absence of an abnormality. It is to be noted that the inspection waveform W1 is not necessarily made up of two types of voltages, and may be made up of three or more types of voltages.

Further, in this embodiment, prior to inspecting the conduction state from the sensor control unit 56 to the liquid detection sensor 84 using the foregoing first sensor inspection processing and second sensor inspection processing, the foregoing main body inspection processing is performed to inspect whether a drive waveform is normally output from the drive waveform generator 52 to the sensor control unit 56. Therefore, in cases where ink in the ink cartridge 80 cannot be detected, it is possible to separately determine whether the cause occurs in the main body (between the drive waveform generator 52 and the sensor control unit 56) of the printing apparatus 10, and whether the cause occurs in a contact portion of the printing apparatus 10 and the ink cartridge 80 (between the sensor control unit 56 and the liquid detection sensor 84). As a result, for example, it is possible to determine a break or a poor contact in a flexible flat cable connecting the drive waveform generator 52 with the sensor control unit 56 as an abnormality on the main body side. In the case where a fuse for over-current protection is provided in an output state of the drive waveform generator 52, it is also possible to determine the blown fuse as an abnormality on the main body side.

Further, in this embodiment, the first sensor inspection processing and the second sensor inspection processing are performed, such that the polarity of the liquid detection sensor 84 is reversed, and the presence or absence of an abnormality is inspected for each polarity. Therefore, even in cases where there is a possibility that the liquid detection sensor 84 behaves differently depending on the polarity, such as a case where the first electrode 85 is in contact with a ground terminal of the semiconductor memory 87, and the second electrode 86 is in contact with a power supply terminal of the semiconductor memory 87, it is possible to achieve an accurate inspection. As a result, if the inspection result for either of the polarities is “NG”, the entire inspection result can be determined to be “NG”. This makes it possible to reduce or eliminate an unpredictable operation of the liquid detection sensor 84.

### D. Modifications

One embodiment of the invention has been described above. However, the invention is not limited to such an embodiment, and various configurations may be employed without departing from the spirit and scope of the invention. For example, the following modifications may be made.

In the foregoing embodiment, the entire main inspection processing is performed when the printing apparatus 10 is powered on. In contrast, for example, in the main inspection processing, only the main body inspection processing is performed when the printing apparatus 10 is powered on, and the first sensor inspection processing and the second sensor inspection processing may be performed at the time when the ink cartridge 80 is replaced. Alternatively, the entire main inspection processing may be performed at the time when the ink cartridge 80 is replaced.

In the foregoing embodiment, the main body inspection processing, the first sensor inspection processing, and the second sensor inspection processing are all performed using the common inspection waveform W1. In contrast, these inspection processing may be performed using respective waveforms that are all different. Alternatively, only the main body inspection processing may be performed using a waveform different from that for other inspection processing.

In the foregoing embodiment, an example in which the invention is applied to a printing apparatus and ink cartridges has been described. However, the invention may be used for a liquid consuming device that ejects and discharges a liquid other than ink, and is applicable to a liquid container containing such a liquid. The liquid container according to an embodiment of the invention can also be diverted to various liquid consuming devices that include a liquid ejecting head for discharging a minute amount of droplets. The term “droplet” refers to the state of a liquid discharged from the liquid consuming device mentioned above, and includes a grain-shaped state, a tear-shaped state, and a long-tailed state. The term “liquid” as used herein may be any material if the liquid consuming device can eject it. Examples of the material may be in a state of the liquid phase of matter, and include liquid states having a high or low viscosity, sol, gel water, other inorganic solvents, organic solvents, solutions, liquid resin, flow states such as liquid metal (molten metal), and not only liquid as one primary state of matter but also materials in which particles of a functional material made up of solid matters such as pigments and metal particles are dissolved, dispersed or mixed in a solvent. As representative examples of the liquid, ink as described in the foregoing embodiment and liquid crystals are mentioned. Here, the term “ink” includes typical water-based ink and oil-based ink, and various liquid compositions such as gel ink and hot melt ink. Specific examples of the liquid consuming device may include a liquid crystal display, an electroluminescent (EL) display, a surface emitting display, a liquid consuming device that ejects liquid containing materials such as electrode materials and color materials used for manufacturing a color filter in the form of dispersion or dissolution, a liquid consuming device that ejects a bio-organic matter used for biochip manufacturing, and a liquid consuming device that is used as a precision pipet and ejects liquid to be a sample. Further, a liquid consuming device that ejects lubricating oil in a pin-point manner to a precision machine such a watch or camera, a liquid consuming device that ejects, onto a substrate, transparent resin liquid of a ultraviolet curing resin or the like for forming a fine hemispherical lens (optical lens) used for an optical communication element, and a liquid consuming device that ejects an etchant of acid, alkali, or the like for etching of a substrate may be employed.

The entire disclosure of Japanese Patent Application No. 2010-124558, filed May 31, 2010 is expressly incorporated by reference herein.

What is claimed is:

1. A printing apparatus in which a liquid container including a liquid detection sensor is mounted, the printing apparatus comprising:
a waveform application unit that applies a first waveform to the liquid detection sensor;
a measuring unit that measures a second waveform output from the liquid detection sensor in response to application of the first waveform; and
an inspection unit that, based on a measurement result of the second waveform, performs an inspection of whether the liquid detection sensor is capable of being driven, wherein
the waveform application unit applies the first waveform to the measuring unit prior to application of the first waveform to the liquid detection sensor,
the measuring unit measures the applied first waveform, and
the inspection unit further performs the inspection based on a measurement result of the first waveform.

2. The printing apparatus according to claim 1, wherein the waveform application unit generates, as the first waveform, a waveform having at least two types of voltages.

3. The printing apparatus according to claim 2, wherein any of the at least two types of voltages is a voltage lower than an input withstand voltage of the measuring unit.

4. The printing apparatus according to claim 2, wherein
the liquid container has a storage element, and
any of the at least two types of voltages is a voltage lower than an input withstand voltage of the storage element.

5. The printing apparatus according to claim 2, wherein the inspection unit determines that a broken wire or a poor contact has occurred in a case where the measured second waveform represents a constant voltage regardless of the application of the first waveform.

6. The printing apparatus according to claim 2, wherein the inspection unit determines that a short-circuit has occurred in a case where the measured second waveform represents the same voltage as the at least two types of voltages that the first waveform has.

7. The printing apparatus according to claim 1, wherein
the liquid detection sensor includes a high-impedance capacitive element,
the waveform application unit applies the first waveform to a first electrode of the capacitive element, and
the measuring unit measures the second waveform output from a second electrode of the capacitive element.

8. The printing apparatus according to claim 7, wherein
the waveform application unit applies the first waveform to the first electrode, and then applies the first waveform to the second electrode, and
the measuring unit measures the second waveform output from the second electrode, and then measures a second waveform output from the first electrode.

9. The printing apparatus according to claim 1, wherein the first waveform applied to the liquid detection sensor and the first waveform applied to the measuring unit are waveforms that are identical in form.

10. An inspection method with which a printing apparatus inspects a liquid detection sensor included in a liquid container mounted in the printing apparatus, the inspection method comprising:
(a) applying a first waveform from the printing apparatus to the liquid detection sensor;
(b) measuring a second waveform output from the liquid detection sensor in response to application of the first waveform;
(c) based on a measurement result of the second waveform, performing an inspection of whether the liquid detection sensor is capable of being driven; and
(d) prior to (a), measuring the first waveform in a state where the first waveform is not applied to the liquid detection sensor, and performing the inspection based on a measurement result of the first waveform.
